(19) United States
(12) Patent Application Publication
(10) Pub. No.: US 2026/0214957 A1
(43) Pub. Date: Jul. 23, 2026

(54) INTERCONNECT INNER SPACER CONFIGURATIONS

(71) Applicant: International Business Machines Corporation, Armonk, NY (US)

(72) Inventors: Xiaoming Yang, Clifton Park, NY (US); Lawrence Alfred Clevenger, Saratoga Springs, NY (US); Yann Mignot, Slingerlands, NY (US); Chanro Park, Clifton Park, NY (US)

(21) Appl. No.: 19/033,934

(22) Filed: Jan. 22, 2025

(51) Int. Cl. H10D 64/01; H01L 21/033; H01L 21/768; H01L 23/528; H10D 84/01; H10D 84/83

(52) U.S. Cl. CPC H10D 64/021; H10D 64/015; H10D 64/017; H10D 84/0147; H10D 84/8316; H10P 76/4085; H10W 20/089; H10W 20/43

(57) ABSTRACT

A method includes providing a semiconductor structure comprising an insulating layer, forming sacrificial mandrel features on top of the insulating layer, and forming a spacer layer by depositing spacer material conformally around the sacrificial mandrel features. The method includes forming a non-mandrel cut region between a first sacrificial mandrel feature and a second sacrificial mandrel feature of the sacrificial mandrel features, forming a first layer region in the non-mandrel cut region, and forming a mandrel cut region by removing a third sacrificial mandrel feature of the sacrificial mandrel features. The method further includes forming a second placeholder layer in the removed portion of the third sacrificial mandrel feature, performing a mandrel pull-back process to remove the first sacrificial mandrel feature and the second sacrificial mandrel feature, and adjusting a thickness of sidewalls of the spacer layer exposed by the mandrel pull-back process.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and costs. Present technology is at or approaching atomic level scaling of certain micro-devices such as logic gates, field-effect transistors (FETs), and capacitors.

### SUMMARY

Embodiments described herein provide techniques for forming interconnect inner spacer configurations.

In one embodiment, a method includes providing a semiconductor structure having a stack of dielectric layers comprising a first insulating layer and a second insulating layer above the first insulating layer, forming a plurality of sacrificial mandrel features on top of the second insulating layer, and forming a spacer layer by depositing spacer material conformally around the sacrificial mandrel features. The method includes forming a non-mandrel cut region between a first sacrificial mandrel feature and a second sacrificial mandrel feature of the plurality of sacrificial mandrel features, forming a first placeholder layer in the non-mandrel cut region, and forming a mandrel cut region by removing at least a portion of a third sacrificial mandrel feature of the plurality of sacrificial mandrel features. The method further includes forming a second placeholder layer in the removed portion of the third sacrificial mandrel feature, performing a mandrel pull-back process to remove at least the first sacrificial mandrel feature and the second sacrificial mandrel feature, and adjusting a thickness of sidewalls of the spacer layer exposed by the mandrel pull-back process, where the adjusting comprises depositing additional spacer material conformally around the spacer layer.

In another embodiment, a method includes providing a semiconductor structure having a stack of dielectric layers comprising a first insulating layer and a second insulating layer above the first insulating layer, forming a plurality of sacrificial mandrel features on top of the second insulating layer, forming a spacer layer by depositing spacer material conformally around the sacrificial mandrel features, and performing a mandrel pull-back process to remove at least a first sacrificial mandrel feature of the plurality of sacrificial mandrel features, where the removed first sacrificial mandrel feature is adjacent to a non-mandrel line comprising a first placeholder layer. The method further includes adjusting a thickness of sidewalls of the spacer layer exposed by the mandrel-pull back process, where the adjusting comprises depositing additional spacer material conformally around the spacer layer, etching continuity line openings into at least the first insulating layer, and forming metal lines in at least a portion of the continuity line openings.

In yet another embodiment, a semiconductor structure includes a substrate, a dielectric interconnect layer positioned on top of the substrate, a plurality of metal lines positioned in the dielectric interconnect layer, a self-aligned mandrel cut region in a first metal line of the plurality of metal lines, and a self-aligned non-mandrel cut region in a second metal line of the plurality of metal lines, where a first spacing between the first metal line and a third metal line adjacent to the first metal line is different than a second spacing between the second metal line and a fourth metal line adjacent to the second metal line.

These and other features and advantages of embodiments described herein will become more apparent from the accompanying drawings and the following detailed description.

### BRIEF DESCRIPTION OF THE DRAWINGS

FIG. 1A is a cross-sectional schematic view of a semiconductor structure during an intermediate fabrication step, in accordance with illustrative embodiments.

FIG. 1B is a top view of the semiconductor structure shown in FIG. 1A.

FIG. 2A is a cross-sectional schematic view of the semiconductor structure following a mandrel formation lithography process, in accordance with illustrative embodiments.

FIG. 2B is a top view of the semiconductor structure shown in FIG. 2A.

FIG. 3A is a cross-sectional schematic view of the semiconductor structure following a mandrel etching process, in accordance with illustrative embodiments.

FIG. 3B is a top view of the semiconductor structure shown in FIG. 3A.

FIG. 4A is a cross-sectional schematic view of the semiconductor structure following a spacer film deposition process, in accordance with illustrative embodiments.

FIG. 4B is a top view of the semiconductor structure shown in FIG. 4A.

FIG. 5A is a cross-sectional schematic view of the semiconductor structure following a mask deposition process for a non-mandrel cut, in accordance with illustrative embodiments.

FIG. 5B is a top view of the semiconductor structure shown in FIG. 5A.

FIG. 6A is a cross-sectional schematic view of the semiconductor structure following a non-mandrel cut process and a fill process for the non-mandrel cut, in accordance with illustrative embodiments.

FIG. 6B is a top view of the semiconductor structure shown in FIG. 6A.

FIG. 7A is a cross-sectional schematic view of the semiconductor structure following an etch back process and an ashing process, in accordance with illustrative embodiments.

FIG. 7B is a top view of the semiconductor structure shown in FIG. 7A.

FIG. 8A is a cross-sectional schematic view of the semiconductor structure following a formation of a flowable chemical vapor deposition (FCVD) layer, in accordance with illustrative embodiments.

FIG. 8B is a top view of the semiconductor structure shown in FIG. 8A.

FIG. 9A is a cross-sectional schematic view of the semiconductor structure following a planarization process, in accordance with illustrative embodiments.

FIG. 9B is a top view of the semiconductor structure shown in FIG. 9A.

FIG. 10A is a cross-sectional schematic view of the semiconductor structure following a mask deposition process for a mandrel cut, a mandrel cut process, and a mandrel fill process, in accordance with illustrative embodiments.

FIG. 10B is a top view of the semiconductor structure shown in FIG. 10A.

FIG. 11A is a cross-sectional schematic view of the semiconductor structure following a mandrel etch back process, in accordance with illustrative embodiments.

FIG. 11B is a top view of the semiconductor structure shown in FIG. 11A.

FIG. 12A is a cross-sectional schematic view of the semiconductor structure following a mandrel pulling process, in accordance with illustrative embodiments.

FIG. 12B is a top view of the semiconductor structure shown in FIG. 12A.

FIG. 13A is a cross-sectional schematic view of the semiconductor structure following a spacer material deposition process, in accordance with illustrative embodiments.

FIG. 13B is a top view of the semiconductor structure shown in FIG. 13A.

FIG. 14A is a cross-sectional schematic view of the semiconductor structure following a spacer material etch back process, in accordance with illustrative embodiments.

FIG. 14B is a top view of the semiconductor structure shown in FIG. 14A.

FIG. 15A is a cross-sectional schematic view of the semiconductor structure following a non-mandrel masking and patterning process, in accordance with illustrative embodiments.

FIG. 15B is a top view of the semiconductor structure shown in FIG. 15A.

FIG. 16A is a cross-sectional schematic view of the semiconductor structure following a non-mandrel etching process and an ashing process, in accordance with illustrative embodiments.

FIG. 16B is a top view of the semiconductor structure shown in FIG. 16A.

FIG. 17A is a cross-sectional schematic view of the semiconductor structure following an insulating layer etching process, in accordance with illustrative embodiments.

FIG. 17B is a top view of the semiconductor structure shown in FIG. 17A.

FIG. 18A is a cross-sectional schematic view of the semiconductor structure following another etching process, in accordance with illustrative embodiments.

FIG. 18B is a top view of the semiconductor structure shown in FIG. 18A.

FIG. 19A is a cross-sectional schematic view of the semiconductor structure following additional etching processes and a plating process, in accordance with illustrative embodiments.

FIG. 19B is a top view of the semiconductor structure shown in FIG. 19A.

### DETAILED DESCRIPTION

Illustrative embodiments may be described herein in the context of illustrative methods for forming inner spacers for interconnect devices, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

Advanced semiconductor fabrication techniques often rely on self-aligned multiple patterning processes. For example, a back-end-of-line (BEOL) interconnect structure may be used to connect device structures, which have been fabricated on a substrate during front-end-of-line (FEOL) processing. Self-aligned patterning processes used to form a BEOL interconnect structure involve linear mandrels acting as sacrificial features that establish a feature pitch. Non-mandrel lines are arranged as linear spaces between sidewall spacers formed adjacent to the sidewalls of the mandrels. After the mandrels are pulled to define mandrel lines, the sidewall spacers are used as an etch mask to etch a pattern predicated on the mandrel lines and the non-mandrel lines into an underlying hardmask. The pattern is subsequently transferred from the hardmask to an interlayer dielectric layer to define trenches in which the wires of the BEOL interconnect structure are formed.

Mandrel cuts may be formed in the mandrels. Non-mandrel cuts may be formed along non-mandrel lines and may include portions of the spacer material used to form the sidewall spacers. The mandrel cuts and non-mandrel cuts are included in the pattern that is transferred to the hardmask and subsequently transferred from the hardmask to form the trenches in the interlayer dielectric layer. The term “cut region” is used herein to refer to a region resulting from a cut (e.g., a non-mandrel cut or a mandrel cut).

In conventional multiple patterning processes, controlling the mandrel dimensions at different feature locations can be a challenge. As fabrication technology moves into the 7-nanometer scale and beyond, the ability to control mandrel and non-mandrel features uniformly across a wafer becomes highly dependent on controlling the critical dimension of a mandrel cut and providing uniform spacing. A spacer feature is generally used to define the space between mandrels and non-mandrel lines.

If the critical dimension for a mandrel cut is too big, the cut cannot be fully pinched-off by a spacer. The result may create a non-mandrel line bridge between features. However, in order to prevent critical dimension pitch variations between features (also known as “pitch-walking”), adjusting spacer thickness arbitrarily is not a reliable solution for conventional techniques. If the critical dimension for mandrel cut is too small, the critical dimension for the cut cannot be patterned. The absence of the mandrel pattern may also create a mandrel line bridge issue. As the scale for patterning becomes smaller, the critical dimension of mandrel cuts and spacer thicknesses can easily vary at every structure being patterned on dies across the entire wafer. Variations in critical dimension for intrinsic cuts (or holes) may pose further challenges in forming uniform patterning features.

Embodiments described herein include using inner spacer deposition and self-aligned cut structures to achieve target critical dimensions in semiconductor manufacturing. In some embodiments, a mandrel cut is performed following a mandrel pull-back process, which allows the relationship between the mandrel critical dimension and spacer thickness to be adjusted to compensate for each other. Such embodiments can provide more flexibility for mandrel etches (e.g., thicker etches), which can at least partially mitigate issues related to mandrel line collapse or instability.

Detailed embodiments of interconnect structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not intended to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc., may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present disclosure.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

The term “mandrel” as used herein generally refers to a linear or ridge-like projection formed on a substrate. In the subject disclosure, a mandrel defines one of the lines on which an interconnect is formed in an underlying layer.

The term “mandrel” as used herein generally refers to a structure that connects two or more circuit elements (such as transistors) together electrically.

The term “self-aligned” as used herein generally refers to patterning of a structure relative to alignment with another structure.

The term “continuity line” as used herein generally refers to a metal or other conductive trace or interconnect.

The term “discontinuity” as used herein generally refers to a break or interruption in a continuity line.

The term “sacrificial” as used herein generally refers to a placeholder feature that will be removed to define a new or different feature.

The term “substrate” as used herein may refer to material that provides a support structure to features in or on top of the substrate material. As used herein, there may be more than one substrate present in an embodiment shown. Also, since embodiments below are generally shown in cross-section, it should be understood that a substrate for a layer with patterned features may not be visible in the view so as to highlight the features for the layer.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

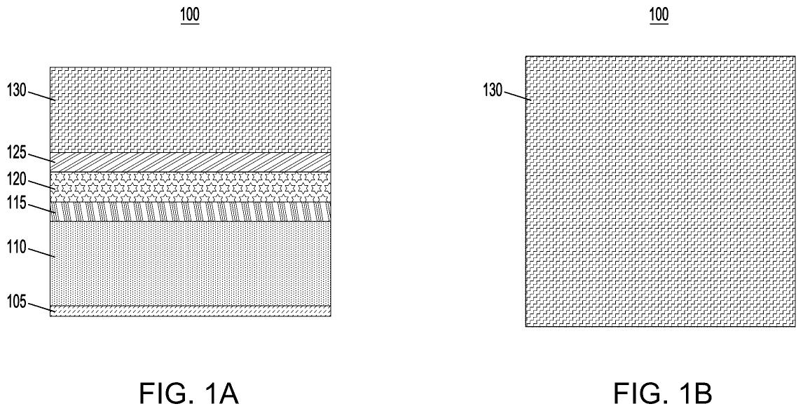

An example of a method for forming a semiconductor device is now described with reference to FIGS. 1A-19B.

FIG. 1A is a cross-sectional schematic view of a semiconductor structure 100 at an intermediate stage of fabrication, and FIG. 1B is a top view of the semiconductor structure 100 shown in FIG. 1A. The semiconductor structure 100 includes a substrate 105 and a stack of dielectric layers formed on top of the substrate 105, including a first insulating layer 115, a spacer layer 120, and a second insulating layer 125. In some embodiments, an interconnect layer 110 may be formed on the substrate 105 prior to formation of the first insulating layer 115. The interconnect layer 110 may be made from a silicon oxycarbonitride (SiCNO) film or another similar dielectric. At the intermediate stage of fabrication shown in FIG. 1A, the interconnect layer 110 does not yet include any interconnect structures.

In at least one embodiment, the substrate 105 may be a bulk semiconductor substrate formed of, for example, silicon, or other types of semiconductor substrate materials that are commonly used in bulk semiconductor fabrication such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AIN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

A dielectric layer 130 for formation of mandrel lines may be deposited on top of the second insulating layer 125.

In one non-limiting example, the substrate 105 can comprise silicon carbonitride and can have a thickness of approximately 8 nm, the interconnect layer 110 can comprise SiCNO and can have a thickness of approximately 40 nm, the first insulating layer 115 can comprise SiON and can have a thickness of approximately 20 nm, the spacer layer 120 can comprise TiN and can have a thickness of approximately 20 nm, the second insulating layer 125 can comprise SiN and can have a thickness of approximately 10 nm, and the dielectric layer 130 can comprise aSi and can have a thickness of approximately 40 nm.

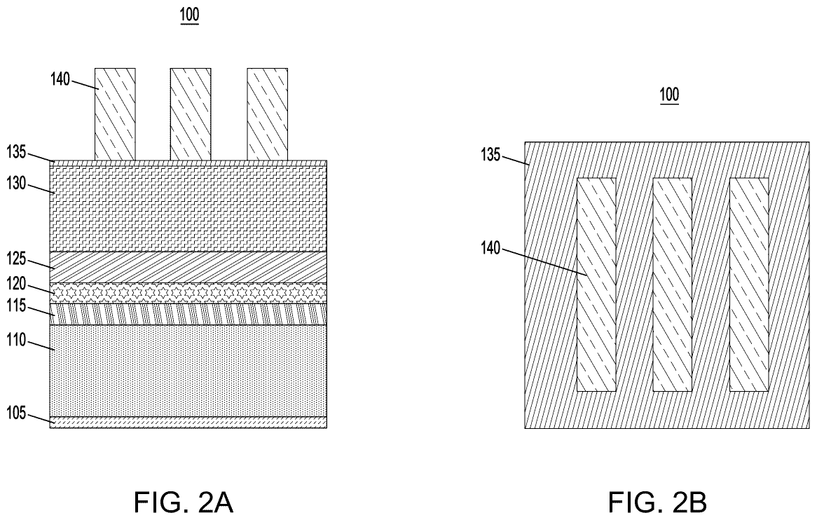

FIGS. 2A and 2B show the formation of an etch mask to pattern the second insulating layer 125. A mask layer 135 (e.g., an organic planarization layer (OPL) or oxide diffusion layer (ODL)) is deposited on top of the dielectric layer 130. Masking rows 140 may be formed on top of the mask layer 135.

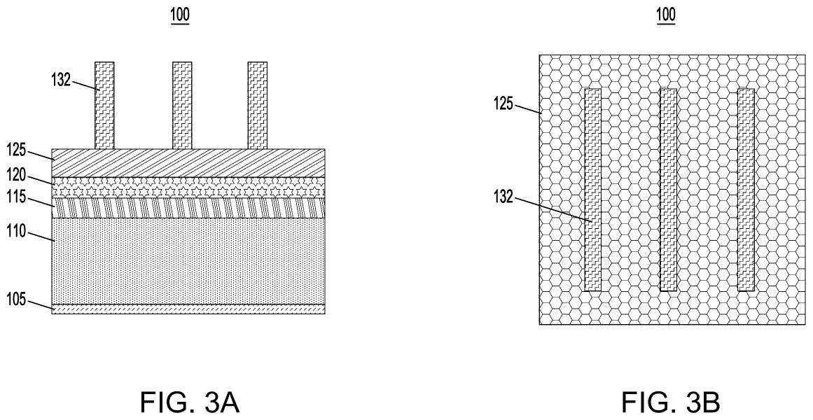

FIGS. 3A and 3B show the semiconductor structure 100 following an etch process that removes the masking rows 140 and mask layer 135, and etches into the dielectric layer 130 to form sacrificial mandrel features 132. In this example, the etching stops at a top surface of the second insulating layer 125.

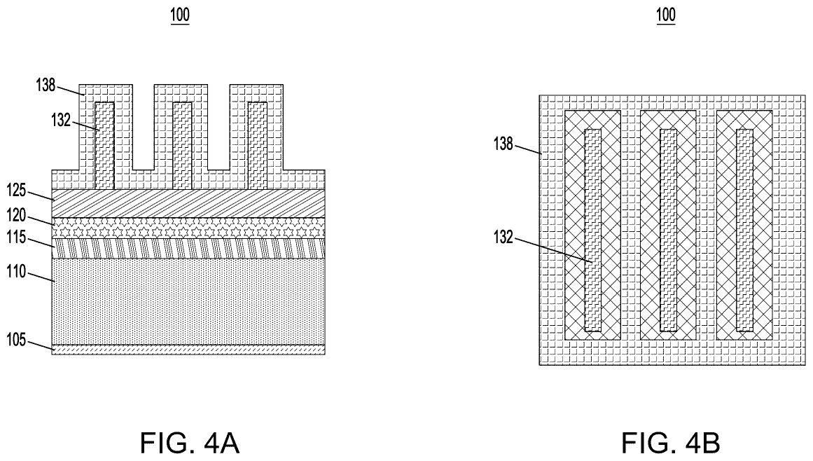

FIGS. 4A and 4B show the semiconductor structure 100 following conformal deposition of a spacer layer 138 surrounding the sacrificial mandrel features 132. In some embodiments, the spacer layer 138 may be the same material as the spacer layer 120, and thus, the same cross-hatching pattern may be used for both films.

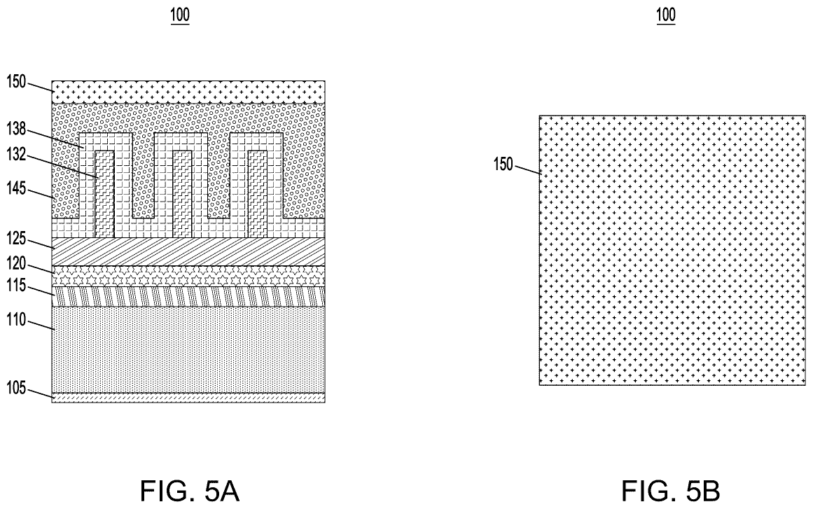

FIGS. 5A and 5B show the semiconductor structure 100 following formation of a temporary insulating layer 145 and an etch mask layer 150. The temporary insulating layer 145 may surround the top surfaces and the side surfaces of the spacer layer 138. The etch mask layer 150 can be formed on a top surface of the temporary insulating layer 145.

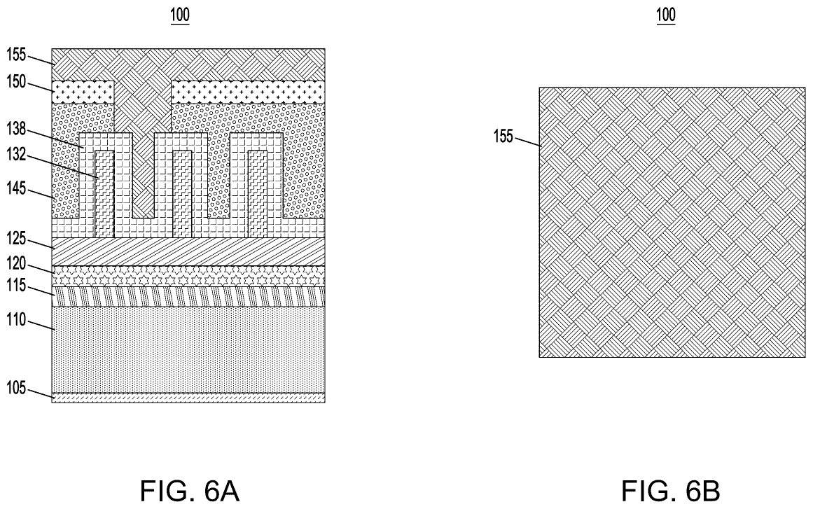

FIGS. 6A and 6B show the semiconductor structure 100 following a non-mandrel cut process and a fill process for the non-mandrel cut. The non-mandrel cut process may include forming a trench that extends through the temporary insulating layer 145 and the etch mask layer 150. The trench exposes the side and bottom surfaces of the spacer layer 138 between the left and center sacrificial mandrel features 132, as well as a portion of the top surface of the spacer layer 138, as shown in FIG. 6A. The trench can be formed using one or more masks (not explicitly shown) and one or more etching processes, for example. A placeholder layer 155 is deposited to fill in the trench and on the top surface of the etch mask layer 150 using for example, electron beam deposition. The placeholder layer 155 may comprise, for example, a gap-fill material such as spin-on-glass (SOG), SiOC, or ALD TiOX.

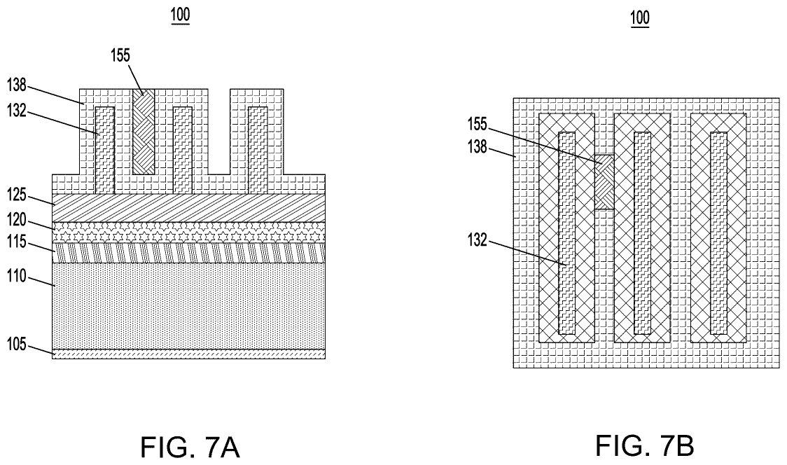

FIGS. 7A and 7B show the semiconductor structure 100 following an etch back process and an ashing process. Specifically, the etch back process removes portions of the placeholder layer 155, the etch mask layer 150, and the temporary insulating layer 145 down to a level corresponding to the top surfaces of the spacer layer 138 that are above the sacrificial mandrel features 132. The ashing process removes the remaining portions of the temporary insulating layer 145. For example, an ashing process can strip the remaining portions of the temporary insulating layer 145 using, for example, oxygen plasma, nitrogen/hydrogen plasma or other carbon strip processes.

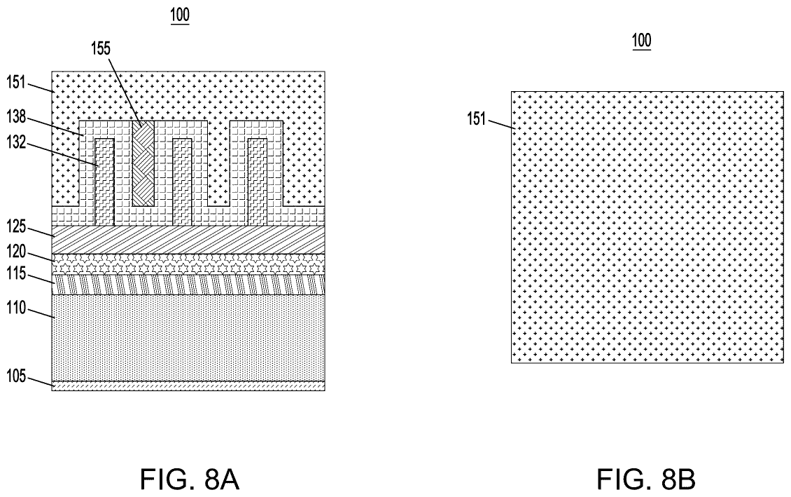

FIGS. 8A and 8B show the semiconductor structure 100 following formation of a flowable chemical vapor deposition (FCVD) layer 151. The FCVD layer 151 fills in spaces around and above the exposed surfaces of the spacer layer 138 and the placeholder layer 155. The FCVD layer 151 can be formed of, for example, an organoaminosilane compound, a trisilylamine compound, or the like.

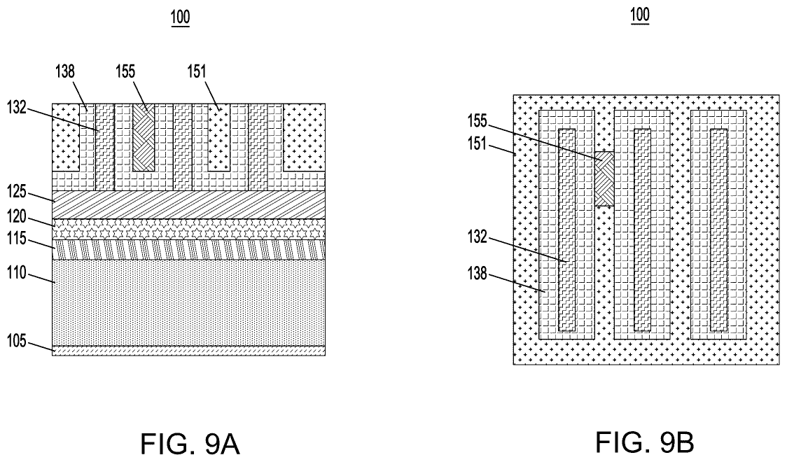

FIGS. 9A and 9B show the semiconductor structure 100 following a planarization process. In some embodiments, the planarization process can include a chemical mechanical planarization (CMP) process that removes the portions of the FCVD layer 151, the placeholder layer 155, and the spacer layer 138 to expose the top surfaces of the sacrificial mandrel features 132.

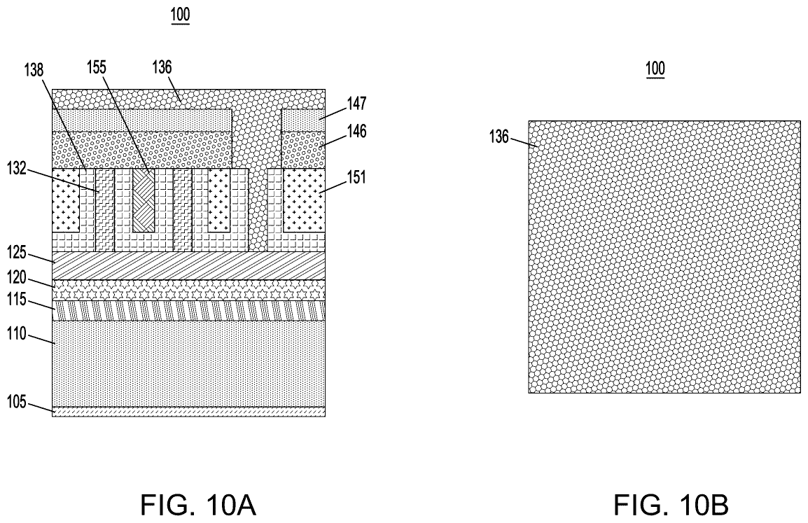

FIGS. 10A and 10B show the semiconductor structure 100 following a mask deposition process for a mandrel cut, a mandrel cut process, and a mandrel fill process, in accordance with illustrative embodiments. The mask deposition process can include forming a temporary insulating layer 146 on a top surface of the semiconductor structure 100 and forming an etch mask layer 147 above the temporary insulating layer 146. The mandrel cut process can include removing the portions of the temporary insulating layer 146 and etch mask layer 147 above the right sacrificial mandrel feature 132 and above the corresponding portions of the spacer layer 138. The right sacrificial mandrel feature 132 is also removed to expose the top surface of the second insulating layer 125. The opening defines a mandrel cut line that is self-aligned relative to the adjacent sidewalls of the spacer layer 138. The mandrel fill process includes filling the opening resulting from the mandrel cut process with a placeholder layer 136. The placeholder layer 136 can be formed using similar techniques and materials as described for the placeholder layer 155, for example.

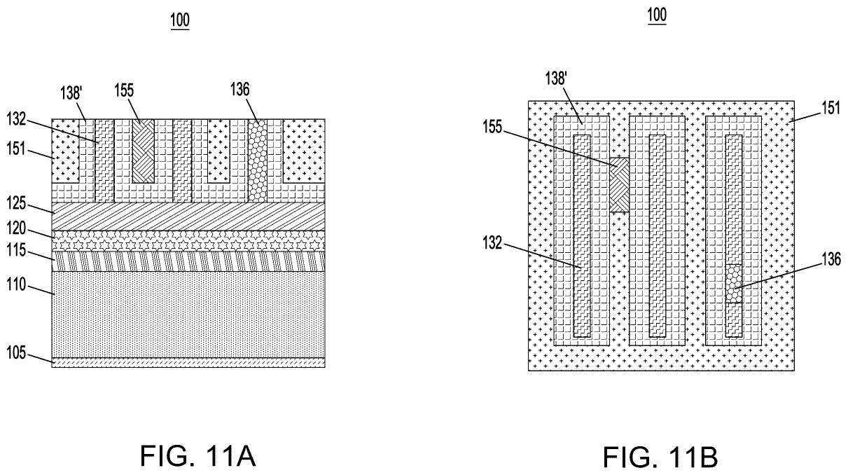

FIGS. 11A and 11B show the semiconductor structure 100 following a mandrel etch back process. The mandrel etch back process removes portions of the etch mask layer 147, the temporary insulating layer 146, and the placeholder layer 136 down to a level corresponding to the top surfaces of the spacer layer 138 and the FCVD layer 151.

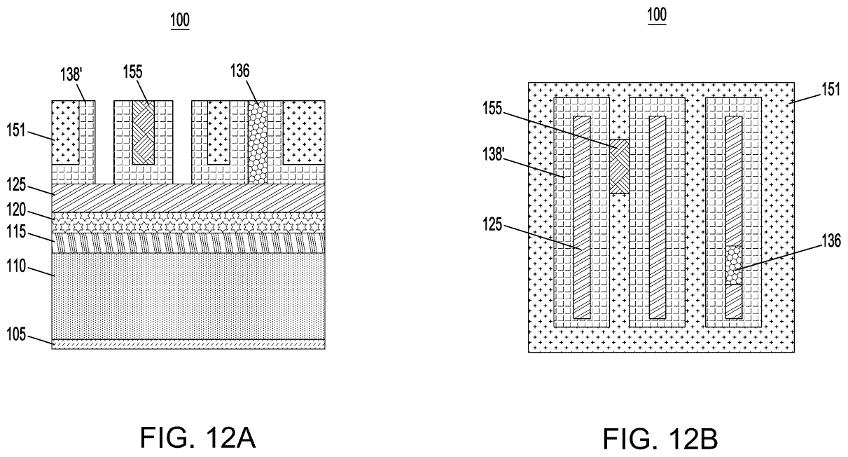

FIGS. 12A and 12B show the semiconductor structure 100 following a mandrel pulling process, in accordance with illustrative embodiments. The mandrel pulling process “pulls” the left and center sacrificial mandrel features 132. For example, the mandrel pulling process can include etching the left and center sacrificial mandrel features 132 selective to the material of the spacer layer 138.

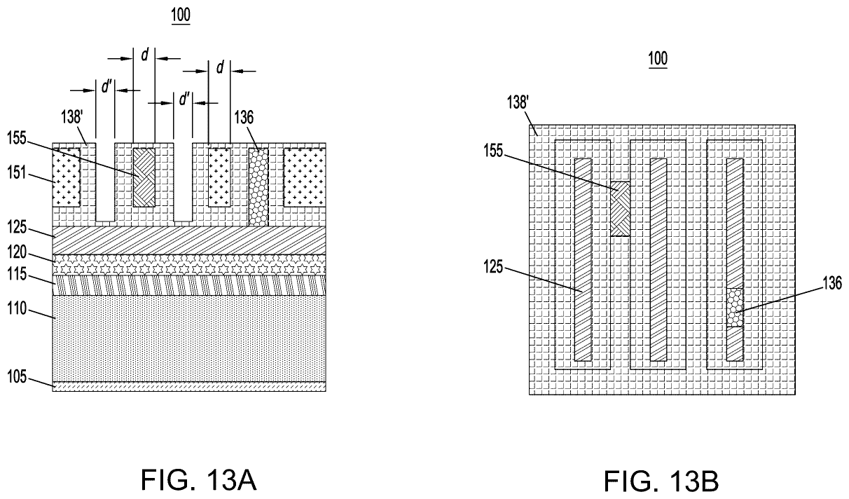

FIGS. 13A and 13B show the semiconductor structure 100 following a spacer material deposition process. The spacer material deposition process can include conformal deposition of additional spacer material on the exposed surfaces of the semiconductor structure 100, thereby forming spacer layer 138′. It is noted that a portion of the FCVD layer 151 and the placeholder layer 155 have a first thickness (identified as d in FIG. 13A) resulting from the non-mandrel cut process described in conjunction with FIGS. 6A and 6B. The spacer material deposition process causes the trenches that were formed by pulling the left and center sacrificial mandrel features 132 to have a second thickness (identified as d′ in FIG. 13A) that is different than d, where d>d′.

In some embodiments, the additional spacer material can have a thickness of approximately 2 nm.

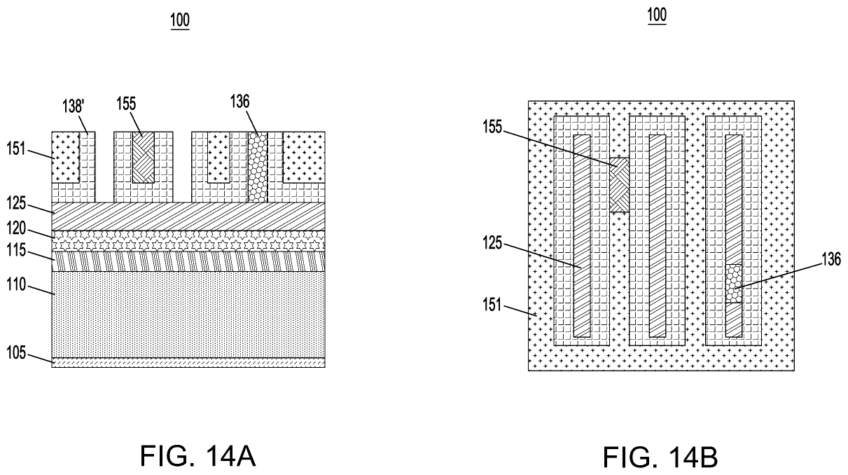

FIGS. 14A and 14B show the semiconductor structure 100 following a spacer material etch back process. The spacer material etch back removes the spacer material from the top surface of the second insulating layer 125 and recesses the top surfaces of the spacer layer 138′ so that they are level with the top surfaces of the FCVD layer 151, the placeholder layer 136, and the placeholder layer 155.

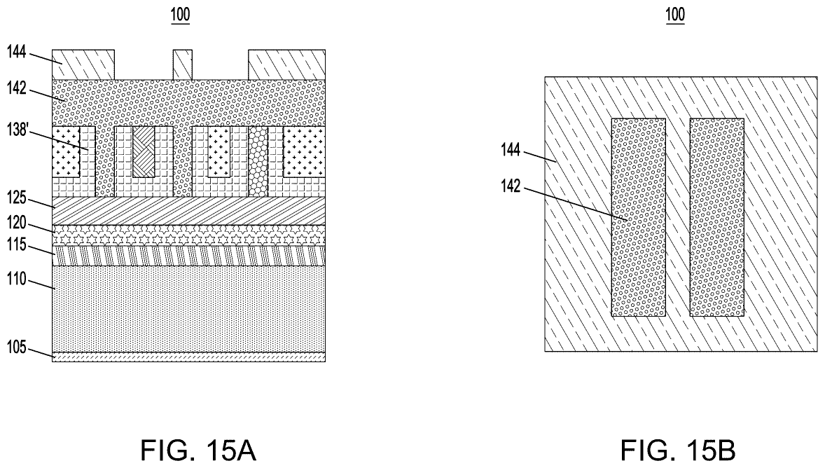

FIGS. 15A and 15B show the semiconductor structure 100 following a non-mandrel masking and patterning process. The non-mandrel masking and patterning process includes forming an OPL 142 and a masking layer 144. Openings are formed in the masking layer 144 for removing a portion of the FCVD layer 151 adjacent to the placeholder layer 136.

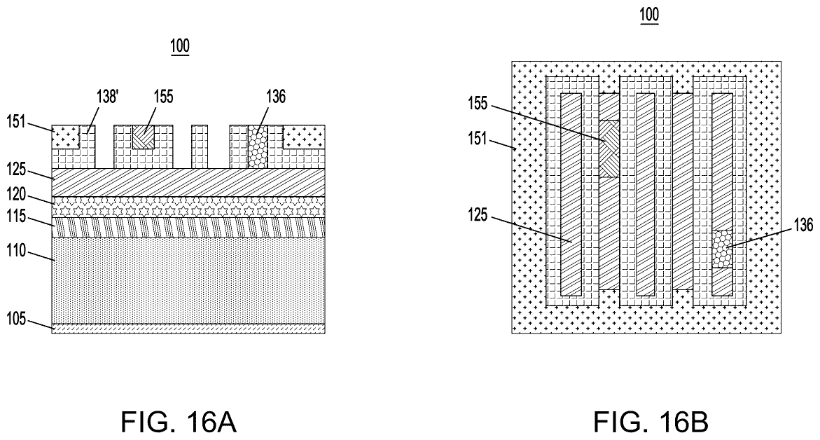

FIGS. 16A and 16B show the semiconductor structure 100 following a non-mandrel etching process and an ashing process. The non-mandrel etching process includes performing one or more etches to remove the portion of the FCVD layer 151 adjacent to the placeholder layer 136 using the OPL 142 and the masking layer 144. In some embodiments, a planarization process (e.g., CMP) is performed to recess the top surface of the semiconductor structure 100. The ashing process strips the remaining OPL 142 from the semiconductor structure 100.

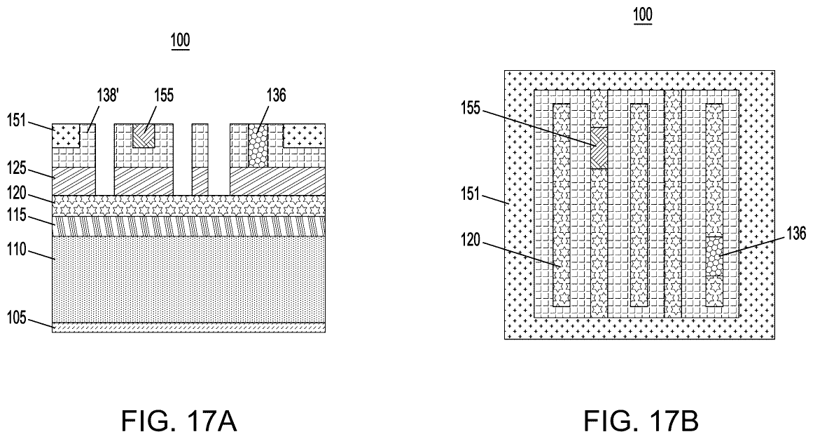

FIGS. 17A and 17B show the semiconductor structure 100 following removal of the exposed portions of the second insulating layer 125 stopping at the spacer layer 120. The portions of the second insulating layer 125 can be removed using one or more etching processes, such as reactive ion etching (RIE).

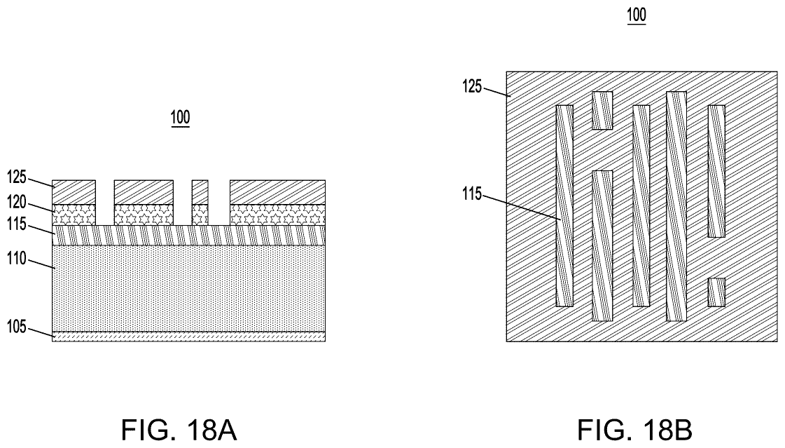

FIGS. 18A and 18B show the semiconductor structure 100 following another etching process. The etching process can include removing the portions of the semiconductor structure above the second insulating layer 125.

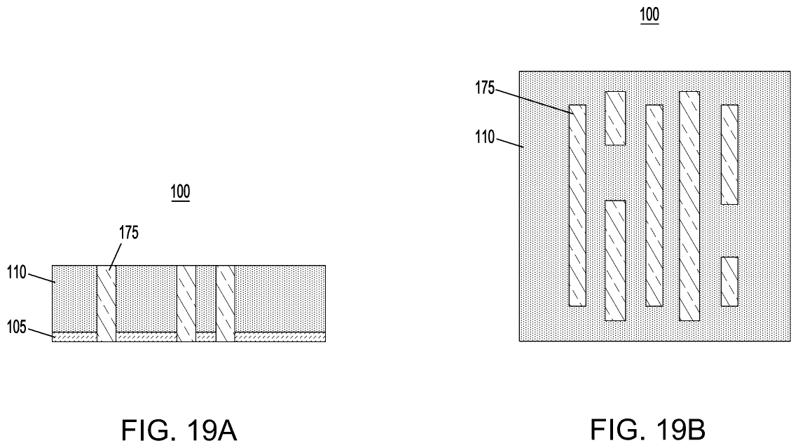

FIGS. 19A and 19B show the semiconductor structure 100 following additional etching processes and a plating process, in accordance with illustrative embodiments. The additional etching processes can include a dielectric etching process that removes the second insulating layer 125 and forms openings down through both the first insulating layer 115 and the substrate 105. The openings define the continuity lines in the interconnect layer 110. The first insulating layer 115 is also removed.

The plating process includes depositing a metal material to form metal lines 175. In the example shown in FIG. 19B, five metal lines 175 are shown. It is to be appreciated that other embodiments may have more or fewer metal lines 175.

The metal lines 175 represent for example, continuity lines in the interconnect layer 110 (or another layer) within the semiconductor device. The metal lines 175 may extend in the same direction. The metal lines 175 may be formed parallel to each other. It is noted that one of the metal lines 175 includes a non-mandrel cut corresponding to the location of the placeholder layer 155, and another one of the metal lines 175 includes a mandrel cut corresponding to the location of the placeholder layer 136. The other metal lines 175 do not include a cut.

It will be understood that other embodiments may include a cut on any of the metal lines 175. In some embodiments, the metal lines 175 that are illustrated with mandrel and non-mandrel cuts may not necessarily have a cut. In yet other embodiments, a metal line 175 may include more than one cut. The non-mandrel cut may be positioned in self-alignment relative to adjacent sidewalls of the interconnect layer 110, while the mandrel cut may be positioned in self-alignment relative to adjacent sidewalls of the interconnect layer 110.

The regions of dielectric material between adjacent ones of the metal lines 175 may be controlled using the techniques described herein, such as by adjusting the thickness of the sidewalls of the spacer layer 138 using the spacer material deposition process described in conjunction with FIGS. 13A and 13B.

In some embodiments, the previously described etching processes may provide openings so that the metal lines 175 are arranged in a staggered array. For example, an end of a first one of the metal lines 175 may be staggered from an end of a second one of the metal lines 175. The non-mandrel cut and mandrel cut can cut the metal lines 175 without clipping any adjacent lines or encroaching on the spacing between metal lines 175.

It is to be appreciated that embodiments described herein perform a mandrel cut following a mandrel pull-back process and then deposit additional spacer material to control the mandrel and non-mandrel cut critical dimensions.

In some embodiments, a thickness of the outer mandrel spacer (e.g., shown in FIGS. 4A and 4B) can be adjusted using, for example, Advanced Process Control (APC) feedback with respect to the thickness of the etching process described in conjunction with FIGS. 3A and 3B. In some embodiments, the inner mandrel spacer thickness described at FIGS. 13A and 13B can be adjusted using APC feedback with respect to the mandrel pull process, as well as the thickness of the outer mandrel spacer described in conjunction with FIGS. 4A and 4B.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a method includes providing a semiconductor structure having a stack of dielectric layers comprising a first insulating layer and a second insulating layer above the first insulating layer, forming a plurality of sacrificial mandrel features on top of the second insulating layer, and forming a spacer layer by depositing spacer material conformally around the sacrificial mandrel features. The method includes forming a non-mandrel cut region between a first sacrificial mandrel feature and a second sacrificial mandrel feature of the plurality of sacrificial mandrel features, forming a first placeholder layer in the non-mandrel cut region, and forming a mandrel cut region by removing at least a portion of a third sacrificial mandrel feature of the plurality of sacrificial mandrel features. The method further includes forming a second placeholder layer in the removed portion of the third sacrificial mandrel feature, performing a mandrel pull-back process to remove at least the first sacrificial mandrel feature and the second sacrificial mandrel feature, and adjusting a thickness of sidewalls of the spacer layer exposed by the mandrel pull-back process, where the adjusting comprises depositing additional spacer material conformally around the spacer layer.

In embodiments, the method further includes etching continuity line openings into at least the first insulating layer, and forming metal lines in the continuity line openings, except where the non-mandrel cut region and the mandrel cut region are disposed.

In embodiments, the method further includes removing the spacer layer prior to etching the continuity line openings.

In embodiments, forming the non-mandrel cut region may include performing at least one self-aligned non-mandrel cut.

In embodiments, forming the mandrel cut region may include performing at least one self-aligned mandrel cut.

In embodiments, Adjusting the thickness of the sidewalls of the spacer layer may be based at least in part on a target critical dimension associated with at least one of the mandrel cut region and the non-mandrel cut region.

In embodiments, adjusting the thickness of the sidewalls of the spacer layer exposed by the mandrel pull-back process may be based at least in part on feedback from the mandrel pull-back process.

In embodiments, adjusting the thickness of the sidewalls of the spacer layer exposed by the mandrel pull-back process may include increasing the thickness of the sidewalls of the spacer layer by at least 2 nm.

In embodiments, adjusting the thickness of the sidewalls of the spacer layer exposed by the mandrel pull-back process many be based at least in part a target critical dimension associated with at least one of the mandrel cut region and the non-mandrel cut region.

In embodiments, the semiconductor structure may include an interconnect layer formed between the stack of dielectric layers and a base substrate.

In embodiments, the first insulating layer and second insulating layer may comprise different materials.

In embodiments, the first placeholder layer and the second placeholder layer may include one or more gap-fill materials.

In another embodiment, a method includes providing a semiconductor structure having a stack of dielectric layers comprising a first insulating layer and a second insulating layer above the first insulating layer, forming a plurality of sacrificial mandrel features on top of the second insulating layer, forming a spacer layer by depositing spacer material conformally around the sacrificial mandrel features, and performing a mandrel pull-back process to remove at least a first sacrificial mandrel feature of the plurality of sacrificial mandrel features, where the removed first sacrificial mandrel feature is adjacent to a non-mandrel line comprising a first placeholder layer. The method further includes adjusting a thickness of sidewalls of the spacer layer exposed by the mandrel-pull back process, where the adjusting comprises depositing additional spacer material conformally around the spacer layer, etching continuity line openings into at least the first insulating layer, and forming metal lines in at least a portion of the continuity line openings.

In embodiments, the first placeholder layer may be formed using a self-aligned non-mandrel cut process.

In embodiments, the method includes forming, prior to performing the mandrel pull-back process, a second placeholder layer using a self-aligned mandrel cut process, wherein the self-aligned mandrel cut process comprises removing a second sacrificial mandrel feature that is different from the first sacrificial mandrel feature, and wherein the second placeholder layer is formed in an area corresponding to the removed second sacrificial mandrel feature.

In embodiments, the metal lines may not be formed in portions of the continuity lines corresponding to where the first placeholder layer and the second placeholder layer are positioned.

In embodiments, adjusting the thickness of the sidewalls of the spacer layer may be based at least in part on a target critical dimension associated with at least one of the self-aligned mandrel cut process and the self-aligned non-mandrel cut process.

In embodiments, adjusting the thickness of the sidewalls of the spacer layer may be based at least in part on feedback from the mandrel pull-back process.

In yet another embodiment, a semiconductor structure includes a substrate, a dielectric interconnect layer positioned on top of the substrate, a plurality of metal lines positioned in the dielectric interconnect layer, a self-aligned mandrel cut region in a first metal line of the plurality of metal lines, and a self-aligned non-mandrel cut region in a second metal line of the plurality of metal lines, where a first spacing between the first metal line and a third metal line adjacent to the first metal line is different than a second spacing between the second metal line and a fourth metal line adjacent to the second metal line.

In embodiments, the first metal line may be parallel to the second metal line.

Conventional techniques for mandrel formation generally achieve a target critical dimension based on a mandrel etch, which can lead to issues such as mandrel line collapse and line stability. Embodiments described herein can advantageously reduce the critical dimensions of mandrels using inner spacer deposition techniques and self-aligned cut structures to achieve target critical dimensions. For example, some embodiments provide more flexibility for mandrel cut critical dimensions by depositing additional spacer material after the mandrel pull process. Such embodiments avoid the issues with smaller mandrel cut critical dimensions, such as mandrel line collapse or instability.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
providing a semiconductor structure having a stack of dielectric layers comprising a first insulating layer and a second insulating layer above the first insulating layer;
forming a plurality of sacrificial mandrel features on top of the second insulating layer;
forming a spacer layer by depositing spacer material conformally around the sacrificial mandrel features;
forming a non-mandrel cut region between a first sacrificial mandrel feature and a second sacrificial mandrel feature of the plurality of sacrificial mandrel features;
forming a first placeholder layer in the non-mandrel cut region;
forming a mandrel cut region by removing at least a portion of a third sacrificial mandrel feature of the plurality of sacrificial mandrel features;
forming a second placeholder layer in the removed portion of the third sacrificial mandrel feature;
performing a mandrel pull-back process to remove at least the first sacrificial mandrel feature and the second sacrificial mandrel feature; and
adjusting a thickness of sidewalls of the spacer layer exposed by the mandrel pull-back process, wherein the adjusting comprises depositing additional spacer material conformally around the spacer layer.

2. The method of claim 1, further comprising:
etching continuity line openings into at least the first insulating layer; and
forming metal lines in the continuity line openings, except where the non-mandrel cut region and the mandrel cut region are disposed.

3. The method of claim 2, further comprising removing the spacer layer prior to etching the continuity line openings.

4. The method of claim 1, wherein forming the non-mandrel cut region comprises performing at least one self-aligned non-mandrel cut.

5. The method of claim 1, wherein forming the mandrel cut region comprises performing at least one self-aligned mandrel cut.

6. The method of claim 1, wherein adjusting the thickness of the sidewalls of the spacer layer is based at least in part on a target critical dimension associated with at least one of the mandrel cut region and the non-mandrel cut region.

7. The method of claim 1, wherein adjusting the thickness of the sidewalls of the spacer layer exposed by the mandrel pull-back process is based at least in part on feedback from the mandrel pull-back process.

8. The method of claim 1, wherein adjusting the thickness of the sidewalls of the spacer layer exposed by the mandrel pull-back process comprises increasing the thickness of the sidewalls of the spacer layer by at least 2 nm.

9. The method of claim 1, wherein adjusting the thickness of the sidewalls of the spacer layer exposed by the mandrel pull-back process is based at least in part a target critical dimension associated with at least one of the mandrel cut region and the non-mandrel cut region.

10. The method of claim 1, wherein the semiconductor structure comprises an interconnect layer formed between the stack of dielectric layers and a base substrate.

11. The method of claim 1, wherein the first insulating layer and second insulating layer comprise different materials.

12. The method of claim 1, wherein the first placeholder layer and the second placeholder layer comprise one or more gap-fill materials.

13. A method comprising:
providing a semiconductor structure having a stack of dielectric layers comprising a first insulating layer and a second insulating layer above the first insulating layer;
forming a plurality of sacrificial mandrel features on top of the second insulating layer;
forming a spacer layer by depositing spacer material conformally around the sacrificial mandrel features;
performing a mandrel pull-back process to remove at least a first sacrificial mandrel feature of the plurality of sacrificial mandrel features, wherein the removed first sacrificial mandrel feature is adjacent to a non-mandrel line comprising a first placeholder layer;
adjusting a thickness of sidewalls of the spacer layer exposed by the mandrel pull-back process, wherein the adjusting comprises depositing additional spacer material conformally around the spacer layer;
etching continuity line openings into at least the first insulating layer; and
forming metal lines in at least a portion of the continuity line openings.

14. The method of claim 13, wherein the first placeholder layer is formed using a self-aligned non-mandrel cut process.

15. The method of claim 14, further comprising:
forming, prior to performing the mandrel pull-back process, a second placeholder layer using a self-aligned mandrel cut process, wherein the self-aligned mandrel cut process comprises removing a second sacrificial mandrel feature that is different from the first sacrificial mandrel feature, and wherein the second placeholder layer is formed in an area corresponding to the removed second sacrificial mandrel feature.

16. The method of claim 15 wherein the metal lines are not formed in portions of the continuity lines corresponding to where the first placeholder layer and the second placeholder layer are positioned.

17. The method of claim 15, wherein adjusting the thickness of the sidewalls of the spacer layer is based at least in part on a target critical dimension associated with at least one of the self-aligned mandrel cut process and the self-aligned non-mandrel cut process.

18. The method of claim 13, wherein adjusting the thickness of the sidewalls of the spacer layer is based at least in part on feedback from the mandrel pull-back process.

19. A semiconductor structure comprising:
a substrate;
a dielectric interconnect layer positioned on top of the substrate;
a plurality of metal lines positioned in the dielectric interconnect layer;
a self-aligned mandrel cut region in a first metal line of the plurality of metal lines; and
a self-aligned non-mandrel cut region in a second metal line of the plurality of metal lines, wherein a first spacing between the first metal line and a third metal line adjacent to the first metal line is different than a second spacing between the second metal line and a fourth metal line adjacent to the second metal line.

20. The semiconductor structure of claim 19, wherein:
the first metal line is parallel to the second metal line.
